(19) United States
(12) Patent Application Publication
(10) Pub. No.: US 2024/0308347 A1
(43) Pub. Date: Sep. 19, 2024

(54) METHOD FOR DETECTING AN UNSTABLE STATE OF A VEHICLE BATTERY

(71) Applicant: Robert Bosch GmbH, Stuttgart (DE)

(72) Inventors: Holger Denz, Stuttgart (DE); Ulf Kleuker, Gerlingen (DE)

(21) Appl. No.: 18/262,360

(22) PCT Filed: Nov. 25, 2021
(86) PCT No.: PCT/EP2021/082932

§ 371 Date: Jul. 20, 2023

(30) Foreign Application Priority Data
Dec. 10, 2020 (DE) 10 2020 215 607.7

(51) Int. Cl. B60L 3/00; B60L 3/12; B60L 53/30

(52) U.S. Cl. CPC B60L 3/0046; B60L 3/12; B60L 53/305; B60L 2240/545; B60L 2240/547; B60L 2240/70

(57) ABSTRACT

The invention relates to a method for detecting an unstable state of a vehicle battery, in particular at least of a traction battery (16) of an electrically powered vehicle (10). At least one traction battery (16) is monitored by a battery monitoring unit (20). In the event that a critical, unstable state occurs, the battery monitoring unit (20) informs a charging communication unit (22) installed on the vehicle. The charging communication unit (22) on the vehicle provides information on the criticality of the current state of the vehicle (10), via a communication interface (32), to a charging communication unit (24) installed on a charging location. In a coordinator (30), which comprises an emergency measure register (34), initiation of measures to reduce the risk and/or danger is requested. The invention further relates to the use of the method for detecting a critical and/or unstable state of at least one traction battery (16) of an electrically powered vehicle (10).

### BACKGROUND

The invention relates to a method for detecting an unstable state of a vehicle battery, in particular of at least one traction battery of an electrically powered vehicle. Moreover, the invention relates to the use of the method for detecting an unstable state of at least one vehicle battery of an electrically powered vehicle.

When rapidly charging batteries of an electric means of transportation, for example at a charging station, relatively high currents occur, which can lead to a high demand on the battery to be recharged. The battery management system of the battery monitors and limits the charging currents of the battery cells of the battery to be charged occurring during charging. If the monitoring and the charging current limiting are not performed correctly, the battery cells of the battery to be recharged can experience a severe heating, which, in particular in the case of lithium-ion battery cells, can lead to a fire.

Thus far, when failure cases occur, only the elimination of the vehicle's readiness to charge at the charging location, for example the charging station, is communicated, which, upon input of a corresponding signal, cancels the charging process. Furthermore, attempts are made to address critical situations of the vehicle battery through vehicle-internal measures. It is known from the charging standard GB/T 27930, valid in China, that temperature and voltage information of the battery cells of the battery to be charged is transmitted to the charging station.

### SUMMARY

According to the invention, a method for detecting an unstable state of a vehicle battery, in particular of at least one traction battery of an electrically powered vehicle, is proposed, in which at least the following method steps are run through:
at least one traction battery is monitored by a battery monitoring unit,
in the event that a critical, unstable state occurs, the battery monitoring unit informs a charging communication unit installed on the vehicle,
the charging communication unit on the vehicle provides information on the criticality of the current state of the vehicle via a communication interface to a charging communication unit installed on a charging location, and
a coordinator, which comprises an emergency measure register, requests initiation of measures to reduce the risk and/or danger.

The method proposed according to the invention can be advantageously used in order to react much more quickly to an unstable state of a traction battery of an electric vehicle and to selectively initiate emergency measures, namely at a very early point in time such that the periphery of a potentially no longer intact electrically powered vehicle is not affected, such as at other electric vehicles to be charged that are parked at further charging locations. With the solution proposed according to the invention, service personnel can be deployed via the management of the charging location, for example a charging station or a charging park, or alternatively or supplementally via the management of the vehicle manufacturer. Likewise, the alerting of the fire department can occur, i.e., a very speedy reaction can take place.

In a further development of the method proposed according to the invention, the criticality of the current state of the vehicle is detected based on information regarding overheating;
loss of battery voltage;
deviations of battery cell temperatures compared to the expected progression during the charging process;
deviations of battery cell voltages compared to the expected progression during the charging process;
deviations of battery cell pressures compared to the expected progression during the charging process;
deviations in battery cell geometry (deformation) compared to the expected progression during the charging process;
detecting gas or liquid leakage from a battery cell;
detecting gases or particles caused by exothermic chemical reactions.

This information can be generated from both vehicle-internal measurements and algorithms of an external IT infrastructure of the vehicle (“digital twin”).

In a further development of the method proposed according to the invention, the initiation of measures to reduce the risk and/or danger by the coordinator is requested by the communication unit on the charging station.

Alternatively, in the method proposed according to the invention, according to d), the initiation of measures to reduce the risk and/or danger by the coordinator can be requested by a management of the charging location. This can be done as a supplement to the request via the vehicle.

In the method proposed according to the invention, the coordinator can alert an emergency service, for example of the vehicle manufacturer, which can determine vehicle-relevant information via remote access on the basis of the parked location of the vehicle, which permits an assessment of the criticality of the vehicle state.

In a further development of the method proposed according to the invention, the coordinator allows a review of all vehicle-relevant information that is performed automatically or by a service person.

In an advantageous embodiment of the method proposed according to the invention, a review of the vehicle-relevant information can be carried out by a service person, the fire department, or via sensors provided by the vehicle, in particular vehicle cameras, temperature sensors, fire or smoke detectors. If intact, the vehicle itself can thus serve as an information provider. The information transmitted in this case can be used in order to reliably determine the criticality of the battery state, which can result in a corresponding state of the vehicle.

In the method proposed according to the invention, all vehicle-relevant information of the vehicle can be reviewed via a remote diagnostic unit installed in the vehicle, which is addressed via a management of the manufacturer of the vehicle. For example, in today's electric vehicles, software updates can be downloaded via the internet, and the vehicle position can be detected at any time via corresponding sensors. This periphery can be advantageously used for safety purposes in order to review all vehicle-relevant information in the event of an unstable state of a traction battery being detected.

In a further advantageous embodiment of the method proposed according to the invention, an independent vehicle-external review of the state of the vehicle is carried out by automated means. For this purpose, the possibly still intact sensor peripherals on the electrically powered vehicle can also be used in order to obtain information for as long as possible, which allows an assessment of a potentially critical vehicle state.

Moreover, the invention relates to the use of the method for detecting a critical and/or unstable state of at least one traction battery of an electrically powered vehicle.

With the solution proposed according to the invention, safety-relevant communication can be detected as quickly as possible in order to recognize requirements for further emergency measures in order to combat a vehicle fire that is likely to break out or has already broken out, caused by an unstable battery. In addition, the solution proposed according to the invention provides the possibility of initiating countermeasures effectively and without a time delay. Thus, the currently very limited safety-relevant communication between an electrically powered vehicle and a charging station to quickly end the charging process can be significantly expanded and supplemented in terms of safety-relevant aspects. The method proposed according to the invention offers great advantages, in particular for the operators of rapid charging points for vehicle traction batteries in enclosed spaces, for example parking lots or underground garages, or also in public places, for example gas stations and shopping centers.

Due to the early information about a potentially critical state of a traction battery provided by the method proposed according to the invention, charging processes of adjacent vehicles can also be interrupted. Moreover, their users can be alerted, and fuses in the power supply can be triggered in order to de-energize a charging periphery, so that a safe access to the critical location is ensured for emergency personnel and so that they can act accordingly. An accelerated access of emergency personnel to the vehicle can be enabled via a corresponding control of the traffic infrastructure (for example, traffic lights, barriers to the parking lot).

With the detected critical deviation of traction battery behavior, field quality systems of the vehicle manufacturer can be enabled for the entire fleet in order to intensify and adjust external (“digital twin”) but also vehicle-internal analysis methods for these vehicle categories. Repair and replacement services can also be scheduled for the individually damaged vehicle.

### BRIEF DESCRIPTION OF THE DRAWING

Embodiments of the invention are explained in more detail with reference to the drawings and the following description.

Shown:

FIG. 1 a schematic representation of the communication between a vehicle and a coordinator with an emergency measure register.

### DETAILED DESCRIPTION

In the following description of the embodiments of the invention, identical or similar elements are denoted by identical reference signs, wherein a repeated description of these elements is omitted in individual cases. The figures illustrate the subject matter of the invention merely schematically.

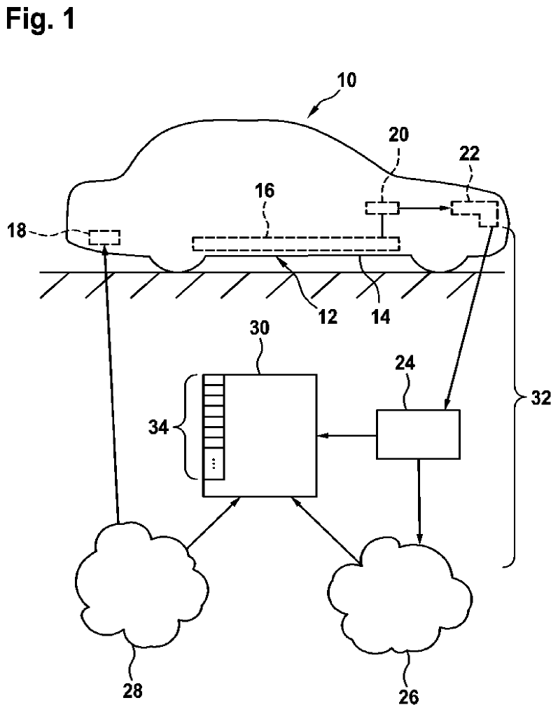

FIG. 1 shows an electrically powered vehicle 10 comprising a chassis 12 with a floor 14 into which a battery 16 is inset. The battery 16 is a traction battery 16 of the electrically powered vehicle 10, which is typically formed as a high-voltage battery. The traction battery 16 accommodated in the floor 14 of the electrically powered vehicle 10 is monitored by means of a battery monitoring unit 20.

In addition to the battery monitoring unit 20, a remote diagnostic unit 18 is accommodated in the electrically powered vehicle 10.

The battery monitoring unit 20 monitoring the at least one traction battery 16 communicates with a charging communication unit 22 on the vehicle.

The charging communication unit 22 on the vehicle communicates with a charging communication unit 24 on a charging location via a communication interface 32. The charging location is, for example, a charging station for rapid charging of the at least one traction battery 16 of the electrically powered vehicle 10.

The charging communication unit 24 on the charging location communicates in turn with a coordinator 30. The coordinator 30 comprises an emergency measure register 34.

From the illustration according to FIG. 1, it can be seen that the charging communication unit 24 on the charging location communicates with a management 26 for charging points. This management 26 also addresses the coordinator 30 along with its emergency measure register 34.

Moreover, the illustration according to FIG. 1 shows that a management 28 of the electrically powered vehicle (back-end vehicle manufacturer) communicates with both the coordinator 30 and the remote diagnostic unit 18 accommodated in the electrically powered vehicle 10. In the event of the occurrence of an unstable or critical state of the at least one traction battery 16 in the electrically powered vehicle 10, this state is detected via the battery monitoring unit 20 and passed on to the charging communication unit 22 on the vehicle. The latter communicates with the vehicle-external charging communication unit 24 on the charging location, for example, accommodated in a charging station. The charging communication unit 24 on the charging location can now address the coordinator 30 directly and request measures from it that lead to a risk reduction or danger reduction associated with the electrically powered vehicle 10. For example, there is the possibility of directing service personnel of the vehicle manufacturer to the electrically powered vehicle 10 or also alerting the fire department.

In the method proposed according to the invention, as a supplementation thereof, the charging communication unit 24 on the charging location can also address the management 26 of the charging locations, which in turn supplementally or additionally addresses the coordinator 30 and requests from it the initiation of measures that lead to a risk or danger reduction associated with the electrically powered vehicle 10.

Alternatively or supplementally, via the management 26 of the charging locations, an automatically controlled review of all information of the electrically powered vehicle 10 can be initiated and, where appropriate, an emergency service can be triggered.

This can be, for example, an independent, vehicle-external review of the vehicle status of an electrically powered vehicle 10, which can be performed either manually by a service employee or by the fire department or automatically via sensors, such as cameras, temperature sensors, fire alarms, and smoke detectors, taking into account the reported criticality of the unstable or critical state of the at least one traction battery 16.

For example, the vehicle-relevant information exchanged between the charging communication unit 22 on the vehicle and the charging communication unit 24 on the charging location via the communication interface 32 includes information such as
an assessment of the criticality of the battery state or the state of individual battery cells based on vehicle-internal readings, such as temperatures, voltages, pressures, determination of deformations of at least one battery cell of traction battery 16;
extended readings of the battery cells (for example, cell pressures, determining the current cell expansion) of the traction battery 16;
detection of gases or liquids exiting a battery cell of the traction battery 16;
detection of gases or particles caused by exothermic chemical reactions in the traction battery of the electrically powered vehicle 10.

Moreover, the illustration according to FIG. 1 shows that the coordinator 30 can be addressed with its emergency measure register not only via the charging communication unit 24 on the charging location and the underlying management 26 (back-end for charging points), but alternatively or supplementally via a management 28 of the vehicle manufacturer (back-end OEM). This means that the management 28 of the vehicle manufacturer of the electrically powered vehicle 10 actuates the remote diagnostic unit 18 installed in the electrically powered vehicle 10, and thus vehicle-relevant information or vehicle-internal data is obtained via the remote diagnostics unit 18. Vehicle-relevant information from vehicle sensors, such as a camera, temperature sensors, fire or smoke detectors, can also be transmitted to the coordinator 30 by the remote diagnostic unit 18, depending on the reported criticality, via the management 28 of the electrically powered vehicle 10. In its emergency measure register 34, for example, an alerting of service employees of the vehicle manufacturer or an alerting of garage personnel can be stored; furthermore, there is a possibility to address the fire department directly; furthermore, vehicles to be charged or their holders, which are located in the periphery of the potentially wrecked electrically powered vehicle 10, can be notified as part of emergency measures; furthermore, there is a possibility of decoupling the rapid charging station from the mains as a whole or segregating corresponding alerts via BS coordinate systems, or the like.

With the method proposed according to the invention, not only a charging process of at least one traction battery 16 of an electrically powered vehicle 10 is advantageously interrupted, but a prevention of potentially expected damage is also achieved by enabling, in the manner of an early warning system, a dissemination of information in a timely manner as well as an identification of the criticality of the state that possibly occurred on the at least one traction battery 16 of the electrically powered vehicle 10 to be charged. With the method proposed according to the invention, the periphery of the environment of the electrically powered vehicle 10 can also be warned in a timely manner. Furthermore, with the method proposed according to the invention, for example by triggering fuses at a charging park with multiple charging stations, it can be achieved that service or garage employees or the fire department can be granted safe access to the critical location.

Thus, the method proposed according to the invention ensures the rapid dissemination of safety-relevant information to the locations that can provide remedy in case of an emergency. The detection of an unstable battery state, for example, which is otherwise only used in order to trigger a charging interruption, can now be used in an advantageous manner for early emergency prevention according to the proposed method, so that further damage may not occur at all if there can be an intervention in a timely manner via emergency personnel, the driver himself, or service employees or garage personnel.

The invention is not limited to the exemplary embodiments described herein and the aspects highlighted thereby. Rather, within the range specified by the claims, a large number of modifications are possible which lie within the abilities of a skilled person.

1. A method for detecting an unstable state of a vehicle battery of an electrically powered vehicle (10), with at least the following method steps:
a) at least one traction battery (16) is monitored by a battery monitoring unit (20),
b) in the event that a critical, unstable state occurs, the battery monitoring unit (20) informs a charging communication unit (22) installed on the vehicle,
c) the charging communication unit (22) on the vehicle provides information on the criticality of the current state of the vehicle (10) via a communication interface (32) to a charging communication unit (24) installed on a charging location, and
d) in a coordinator (30), which comprises an emergency measure register (34), initiation of measures to reduce the risk and/or danger is requested.

2. The method according to claim 1, wherein, according to c), the criticality of the current state of the vehicle (10) is determined based on information about
the overall criticality of the traction battery (16) or the criticality of individual battery cells of the traction battery (16) determined from vehicle-internal readings such as temperatures, voltages, pressures, determination of deformations of at least one battery cell of the traction battery (16);
extended readings of the battery cells of the traction battery (16);
the detection of gases or liquids exiting a battery cell of the traction battery (16), and
the detection of gases or particles caused by exothermic chemical remeasures in the traction battery (16).

3. The method according to claim 1, wherein, according to d), the initiation of measures to reduce the risk and/or danger is requested at the coordinator (30) by the communication unit (24) on a charging location.

4. The method according to claim 1, wherein, according to d), the initiation of measures for risk and/or risk reduction is requested at the coordinator (30) by a management (26) of a charging unit.

5. The method according to claim 1, wherein the coordinator (30) triggers an emergency service.

6. The method according to claim 1, wherein the coordinator (30) triggers a review of all vehicle-relevant information that is performed automatically or by a service person.

7. The method according to claim 6, wherein the review of the vehicle-relevant information is carried out via sensors.

8. The method according to claim 6, wherein all vehicle-relevant information of the vehicle (10) is reviewed via a remote diagnostic unit (18) in the vehicle (10), which is addressed via a management (28) of the manufacturer of the vehicle (10).

9. The method according to claim 1, wherein an independent, vehicle-external review of the state of the vehicle (10) is initiated by the management of the charging points (26).

10. The method according to claim 1, wherein an independent, vehicle-external review of the state of the vehicle (10) is initiated by a management (28) of the vehicle manufacturer.

11. A use of the method according to claim 1 for detecting a critical and/or unstable state of at least one traction battery (16) of an electrically powered vehicle (10).
